(19) United States
(12) Patent Application Publication
(10) Pub. No.: US 2025/0105203 A1
(43) Pub. Date: Mar. 27, 2025

(54) SOLDERING APPARATUS, METHOD FOR MANUFACTURING SEMICONDUCTOR PACKAGE USING THE SAME, AND METHOD FOR MANUFACTURING SOLDERING APPARATUS

(71) Applicant: SAMSUNG ELECTRONICS CO., LTD., Suwon-si (KR)

(72) Inventors: Kyung Deuk MIN, Suwon-si (KR); Sin Yeop LEE, Suwon-si (KR); Tae Gyu KANG, Suwon-si (KR); Myeong Hyeon YU, Suwon-si (KR); Jae-Seon HWANG, Suwon-si (KR)

(21) Appl. No.: 18/669,933

(22) Filed: May 21, 2024

(30) Foreign Application Priority Data
Sep. 21, 2023 (KR) 10-2023-0126137

(51) Int. Cl. H01L 23/00; B23K 1/005; B23K 3/08; B23K 101/42

(52) U.S. Cl. CPC H01L 24/75; B23K 1/005; B23K 3/08; H01L 24/81; B23K 2101/42; H01L 2224/75253; H01L 2224/8122; H01L 2224/81815

(57) ABSTRACT

A soldering apparatus includes a stage on which a plurality of electronic devices are loaded, a light source disposed on the stage and configured to cast light toward the plurality of electronic devices, and a mask film disposed between the light source and the plurality of electronic devices. The mask film has openings exposing at least a portion of each of the plurality of electronic devices and a guide is connected to the mask film and extends toward the plurality of electronic devices. The guide includes a reflective material.

### CROSS-REFERENCE TO RELATED APPLICATION

This application claims priority under 35 U.S.C. § 119 to Korean Patent Application No. 10-2023-0126137, filed on Sep. 21, 2023 in the Korean Intellectual Property Office, the contents of which in its entirety are herein incorporated by reference.

### TECHNICAL FIELD

The present disclosure relates to soldering and, more specifically, to a soldering apparatus, a method for manufacturing a semiconductor package using the same, and a method for manufacturing the soldering apparatus.

### DISCUSSION OF THE RELATED ART

With rapid development of the electronics industry, high-performance semiconductors are in demand. In accordance with this demand, various devices are being mounted on a semiconductor package. Various methods, such as wire bonding and soldering, are used to mount the devices thereon. When soldering, the devices are mounted on the semiconductor package by applying heat using a heat source such as hot air or a laser.

In particular, recently, an IPL (intense pulsed light) soldering scheme, which melts a solder paste by applying heat using light, has been studied.

### SUMMARY

A soldering apparatus includes a stage on which a plurality of electronic devices are loaded. A light source is disposed on the stage and is configured to cast light toward the plurality of electronic devices. A mask film is disposed between the light source and the plurality of electronic devices. The mask film has openings exposing at least a portion of each of the plurality of electronic devices. A guide is connected to the mask film and extends toward the plurality of electronic devices. The guide includes a reflective material.

A soldering apparatus includes a stage on which a PCB substrate. First and second electronic devices are disposed on the PCB substrate and are loaded. A light source is disposed on the stage and is configured to provide light toward the first and second electronic devices. A mask film is disposed between the light source and the first and second electronic devices and exposes the first and second electronic devices. A reflective film is disposed on at least a portion of a surface of the mask film. The mask film includes a horizontal portion having a first opening exposing the first electronic device, and a second opening exposing the second electronic device, a first vertical portion extending from an end of the first opening toward the first electronic device, and a second vertical portion extending from an end of the second opening toward the second electronic device. The reflective film includes a reflective material.

A method for manufacturing a semiconductor package includes loading a PCB substrate. Solder paste is applied on the PCB substrate. A plurality of electronic devices are placed on the solder paste. A mask film is placed on the plurality of electronic devices. Light is cast toward the plurality of electronic devices using a light source spaced apart from the plurality of electronic devices to perform a light soldering process. The mask film is disposed between the light source and the plurality of electronic devices. The mask film includes a horizontal portion having an opening defined therein exposing at least a portion of each of the plurality of electronic devices, and a vertical portion extending from an end of the opening toward each of the plurality of electronic devices. A reflective material is coated on a surface of the vertical portion.

A method for manufacturing a soldering apparatus includes providing first and second electronic devices. A mask film is formed having a first opening exposing an upper surface of the first electronic device and a second opening exposing an upper surface of the second electronic device. A first guide is formed extending vertically from an end of the first opening. A second guide is formed extending vertically from an end of the second opening. A length of the first guide is determined based on a height of the first electronic device. A length of the second guide is determined based on a height of the second electronic device.

### BRIEF DESCRIPTION OF DRAWINGS

The above and other aspects and features of the present disclosure will become more apparent by describing in detail illustrative embodiments thereof with reference to the attached drawings, in which:

FIG. 1 is a diagram illustrating a soldering apparatus according to embodiments of the present disclosure.

FIG. 2 is an enlarged view of an area P shown in FIG. 1.

FIGS. 3 to 8 are diagrams illustrating a soldering apparatus according to embodiments of the present disclosure.

FIG. 9 is a diagram illustrating a soldering apparatus according to embodiments of the present disclosure.

FIG. 10 is an enlarged view of a Q area in FIG. 9.

FIGS. 11 to 15 are diagrams illustrating a soldering apparatus according to embodiments of the present disclosure.

FIGS. 16 to 23 are diagrams illustrating a method of manufacturing a semiconductor package using a soldering apparatus according to embodiments.

FIGS. 24 to 27 are diagrams illustrating a method of manufacturing a soldering apparatus according to some embodiments.

FIGS. 28 to 30 are diagrams illustrating a method of manufacturing a soldering apparatus according to embodiments.

### DETAILED DESCRIPTIONS

Although terms such as first and second are used to describe various elements or components in the present specification, these elements or components are not necessarily limited by these terms. These terms are used to distinguish a single element or component from other elements or components. Therefore, a first element or component referred to below may be a second element or component within the technical idea of the present disclosure.

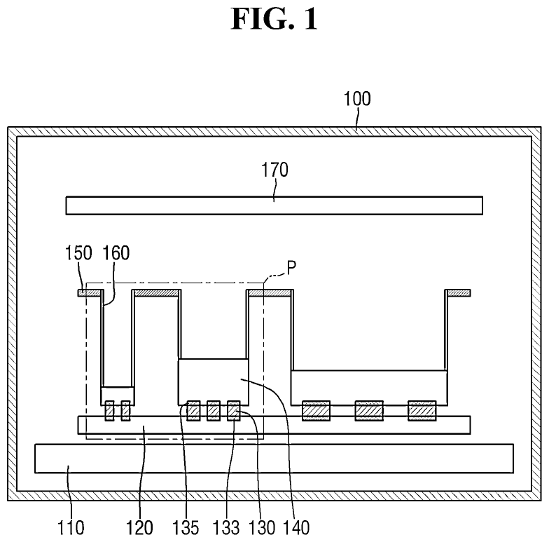

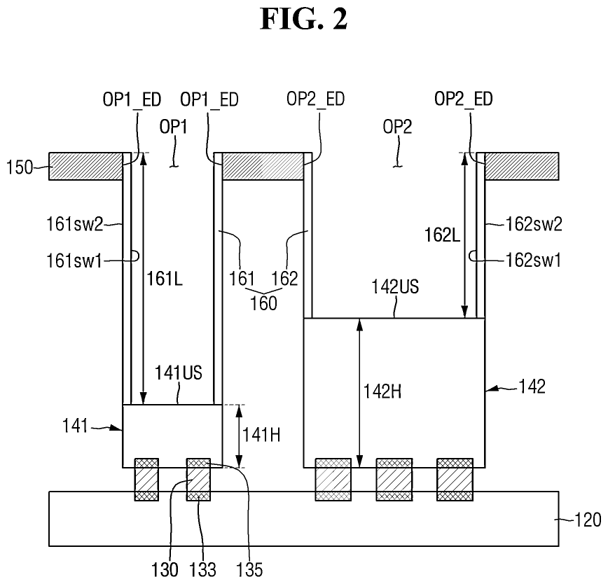

Hereinafter, a soldering apparatus according to some embodiments is described with reference to FIG. 1 and FIG. 2. FIG. 1 is a diagram illustrating a soldering apparatus according to some embodiments of the present disclosure.

First, referring to FIG. 1, a soldering apparatus, according to embodiments, may include a housing 100, a stage 110, a mask film 150, a guide 160, and a light source 170. The soldering apparatus, in accordance with the present disclosure, may be an apparatus that performs a soldering process when manufacturing a semiconductor package. For example, the soldering apparatus, in accordance with the present disclosure, may be an apparatus that performs a light soldering process using light.

The housing 100 may define a process area where a light soldering process is performed. A general appearance of the housing 100 may have a shape of a cylinder, an elliptical column, or a polygonal column. The housing 100 is generally made of a metal material, and may block ambient noise.

The stage 110 may be provided inside the housing 100. The stage 110 may be an area on which electronic devices or a PCB substrate on which the soldering process is to be performed are mounted. For example, a PCB substrate 120 may be disposed on the stage 110, and a plurality of electronic devices 140 may be disposed on the PCB substrate 120.

The PCB substrate 120 may be a package substrate. The PCB substrate 120 may be a printed circuit board (PCB). The plurality of electronic devices 140 may be mounted on an upper surface of the PCB substrate 120. Various connection members may be disposed on a lower surface of the PCB substrate 120. The PCB substrate 120 may be connected to a main board of an electronic device, etc. via the connection member. Thus, the main board of the electronic device, etc. may be electrically connected to the plurality of electronic devices 140.

In some embodiments, the PCB substrate 120 may include a copper clad laminate (CCL). For example, the PCB substrate 120 may have a structure in which a copper laminate is laminated on one surface or each of both opposing surfaces of a thermoset prepreg (e.g., C-Stage prepreg).

The plurality of electronic devices 140 may be mounted on the PCB substrate 120. The plurality of electronic devices 140 may be disposed on the PCB substrate 120. The plurality of electronic devices 140 may be a semiconductor chip, a semiconductor package, and/or a passive clement including a multi-layer ceramic condenser (MLCC). For example, in FIG. 1 and FIG. 2, an example in which the plurality of electronic devices 140 are embodied as semiconductor chips is illustrated. However, the technical idea of the present disclosure is not necessarily limited thereto. A first electronic device 141 may be a semiconductor chip and a second electronic device may be an MLCC.

When each of the plurality of electronic devices 140 is embodied as the semiconductor chip, the semiconductor chip may be a memory chip or a logic chip.

In one example, each of the plurality of electronic devices 140 may include a central processing unit (CPU), a graphic processing unit (GPU), a field-programmable gate array (FPGA), an application processor (AP) such as a digital signal processor, a cryptographic processor, a microprocessor, a microcontroller, an application-specific IC (ASIC), etc.

In an example, each of the plurality of electronic devices 140 may be a volatile memory such as dynamic random access memory (DRAM) or static random access memory (SRAM), or may be non-volatile memory, such as flash memory, phase-change random access memory (PRAM), magnetoresistive random access memory (MRAM), ferroelectric random access memory (FeRAM), or resistive random access memory (RRAM). However, the technical idea of the present disclosure is not necessarily limited thereto.

Each of the plurality of electronic devices 140 may include a chip pad 135. The chip pad 135 may be used to electrically connect each of the plurality of electronic devices 140 with other components. For example, the chip pad 135 might not be covered with a lower surface of each of the plurality of electronic devices 140. A plurality of chip pads 135 may be disposed under one electronic device 140.

The PCB substrate 120 may include a substrate pad 133. The substrate pad 133 may be used to electrically connect the PCB substrate 120 to other components. For example, the substrate pad 133 might not be covered with an upper surface of the PCB substrate 120. The substrate pad 133 may be electrically connected to the chip pad 135 via a solder ball 130, which will be described later. Thus, the PCB substrate 120 and each of the plurality of electronic devices 140 may be electrically connected to each other.

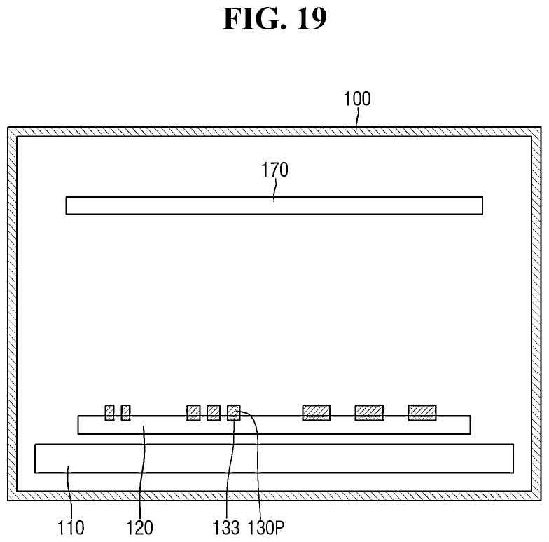

The solder ball 130 may be disposed between the substrate pad 133 and the chip pad 135. The solder ball 130 may be formed by applying a solder paste (130P in FIG. 19) and then melting the solder paste. The solder paste may be melted by casting light thereto to apply heat thereto. The solder ball 130 may include a low melting point metal, such as tin (Sn), copper (Cu), silver (Ag), and/or alloys thereof or bismuth (Bi). The solder ball 130 may have various shapes such as a land, a ball, a pin, or a pillar.

The light source 170 may be disposed on top of the stage 110. The light source 170 may be disposed within the housing 100. The light source 170 may be spaced apart from the plurality of electronic devices 140. The light source 170 may cast light toward the plurality of electronic devices 140. In some embodiments, the light source 170 may be a xenon lamp. For example, the light source 170 may be a xenon flash lamp. A wavelength of light from the xenon flash lamp may be in a range from about 185 nm to about 2000 nm, or from about 400 nm to about 1200 nm.

In some embodiments, the light may be intense pulsed light (IPL). The IPL refers to short, strong pulsed light with a wide wavelength spectrum. The IPL has the advantage of being able to cast light of multiple wavelengths onto a large area and exposing the light of a short pulse with high intensity to an area to selectively heat the area. In some embodiments, the frequency of the IPL may be about 2 Hz or greater. For example, the frequency of IPL may be in a range of approximately 2 Hz to 4 Hz. In some embodiments, the number of pulses of IPL may be about 6 or more. For example, the number of pulses of IPL may be in a range of about 6 to about 8. However, the technical idea of the present disclosure is not necessarily limited thereto.

The mask film 150 may be disposed between the light source 170 and the plurality of electronic devices 140. The mask film 150 may block a portion of the light provided from the light source 170. The mask film 150 may limit an area to which the light is cast. For example, the light might not be cast to a portion screened with the mask film 150. Alternatively, even when the light is cast to the portion, a heat amount sufficient to melt the solder paste might not be provided thereto. The mask film 150 may include an opening defined therein exposing each of the plurality of electronic devices 140. The light may be provided to each of the plurality of electronic devices 140 through the opening. The light does not travel through the mask film 150.

The guide 160 may be connected to the mask film 150 and extend toward the plurality of electronic devices 140. The guide 160 may prevent the light provided from the light source 170 from being provided to other unwanted areas. For example, the guide 160 may include a reflective material. Therefore, the guide 160 may reflect the light therefrom.

For example, the reflective material may be a polymer material such as PPA (polyphthalamide) or a highly reflective metal powder or ceramic powder. The highly reflective ceramic powder may be made of TiO₂, Al₂O₃, Nb₂O₅, Al₂O₃, and/or ZnO. The highly reflective metal powder may be made of aluminum (Al) or silver (Ag). Furthermore, the reflective material may be a material acting as a mirror. However, the technical idea of the present disclosure is not necessarily limited thereto.

Hereinafter, with reference to FIG. 2, the mask film 150 and the guide 160 are described in more detail. FIG. 2 is an enlarged view of a P area in FIG. 1.

Referring to FIG. 2, the mask film 150, according to some embodiments may include a first opening OP1 and a second opening OP2 defined therein. The plurality of electronic devices 140 may include a first electronic device 141 and a second electronic device 142.

The first opening OP1 may expose the first electronic device 141. The first opening OP1 may expose an upper surface 141US of the first electronic device 141. The first opening OP1 may entirely expose the upper surface 141US of the first electronic device 141. For example, in a cross-sectional view, a width of the first opening OP1 may be equal to a width of the upper surface 141US of the first electronic device 141. Furthermore, in a plan view, an area size of the first opening OP1 may be equal to an area size of the first electronic device 141.

The second opening OP2 may expose the second electronic device 142. The second opening OP2 may expose an upper surface 142US of the second electronic device 142. For example, in the cross-sectional view, a width of the second opening OP2 may be equal to a width of the upper surface 142US of the second electronic device 142. Furthermore, in the plan view, an area size of the second opening OP2 may be equal to an area size of the second electronic device 142.

The guide 160 may be connected to the mask film 150. In some embodiments, the guide 160 may include a first guide 161 and a second guide 162.

The first guide 161 may extend from an end OP1_ED of the first opening OP1 toward the first electronic device 141. The end OP1_ED of the first opening OP1 may be a boundary between the mask film 150 and the first opening OP1.

The first guide 161 may extend vertically from the end OP1_ED of the first opening OP1 toward the first electronic device 141. The vertical direction may be perpendicular to the upper surface 141US of the first electronic device 141. For example, in a cross-sectional view, a distance between the first guides 161 adjacent to each other may be constant as the first guides 161 extend from the mask film 150 toward the first electronic device 141. However, the technical idea of the present disclosure is not necessarily limited thereto.

The second guide 162 may extend from an end OP2_ED of the second opening OP2 toward the second electronic device 142. The end OP2_ED of the second opening OP2 may be a boundary between the mask film 150 and the second opening OP2.

The second guide 162 may extend vertically from the end OP2_ED of the second opening OP2 toward the second electronic device 142. The vertical direction may be perpendicular to the upper surface 142US of the second electronic device 142. For example, in a cross-sectional view, a distance between the second guides 162 adjacent to each other may be constant as the second guides 162 extends from the mask film 150 toward the second electronic device 142. However, the technical idea of the present disclosure is not necessarily limited thereto.

In some embodiments, the first guide 161 may include a first sidewall 161sw1 facing the first opening OP1 and a second sidewall 161sw2 opposite thereto. In the cross-sectional view, a spacing between the first sidewalls 161sw1 may be constant as the first sidewalls 161sw1 extend from the mask film 150 toward the first electronic device 141. Furthermore, the second guide 162 may include a third sidewall 162sw1 facing the second opening OP2 and a fourth sidewall 162sw2 opposite thereto. In the cross-sectional view, a spacing between the third sidewalls 162sw1 may be constant as the third sidewalls 162sw1 extend from the mask film 150 toward the second electronic device 142. However, the technical idea of the present disclosure is not necessarily limited thereto.

In some embodiments, a length 161L of the first guide 161 may be different from a length 162L of the second guide 162. For example, the length 161L of the first guide 161 may be greater than the length 162L of the second guide 162. In some embodiments, the length of the guide 160 may be determined based on a size of a corresponding electronic device 140. In one example, when a height of the electronic device 140 is large, a length of the guide 160 corresponding to the electronic device may be small. Conversely, when the height of the electronic device 140 is small, the length of the corresponding guide 160 thereto may be large.

In FIG. 2, a height 141H of the first electronic device 141 is smaller than a height 142H of the second electronic device 142. Accordingly, the length 161L of the first guide 161 may be greater than the length 162L of the second guide 162. This may be because the first guide 161 is not vertically spaced from the first electronic device 141, and the second guide 162 is not vertically spaced from the second electronic device 142. However, the technical idea of the present disclosure is not necessarily limited thereto.

Likewise, an area size of the opening may be determined based on an area size of the corresponding electronic device 140. In one example, when the area size of the electronic device 140 is large, the area size of the corresponding opening may be large. Conversely, when the area size of the electronic device 140 is small, the area size of the corresponding opening may be small.

In FIG. 2, a width of the first electronic device 141 is smaller than a width of the second electronic device 142. Therefore, a width of the first opening OP1 may be smaller than a width of the second opening OP2. However, the technical idea of the present disclosure is not necessarily limited thereto.

In some embodiments, the mask film 150 may include a metallic material and the guide 160 may include a reflective material. When performing a light soldering process using the soldering apparatus according to some embodiments of the present disclosure, the light may travel through the opening and be provided to the electronic device 140. At this time, the light does not travel through the guide 160. The guide 160 reflects the light therefrom. Therefore, the light may be prevented from being cast to an unwanted area. The light may be selectively cast only to an area on which the light soldering process is to be performed. Accordingly, a semiconductor package with increased reliability may be manufactured.

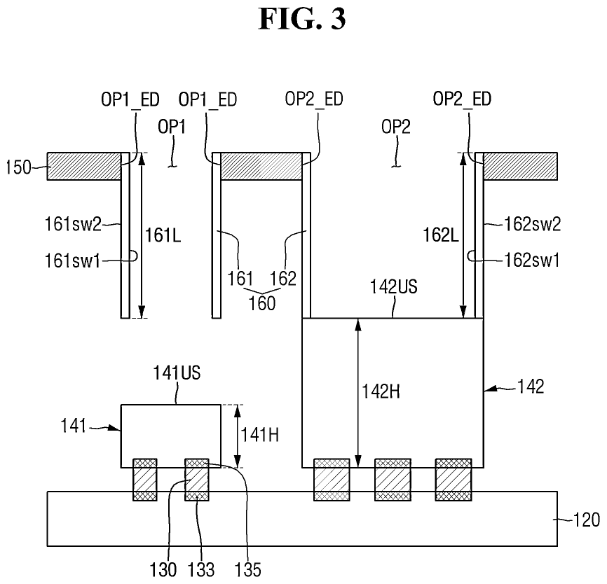

Hereinafter, a soldering apparatus according to some embodiments of the present disclosure is described above using FIGS. 3 to 8. FIGS. 3 to 8 are diagrams illustrating a soldering apparatus according to some embodiments of the present disclosure.

First, referring to FIG. 3, the first guide 161 may be spaced apart from the first electronic device 141 in the vertical direction. The second guide 162 is not spaced apart from the second electronic device 142 in the vertical direction. In this regard, the length 161L of the first guide 161 may be equal to the length 162L of the second guide 162. However, the technical idea of the present disclosure is not necessarily limited thereto. The length 161L of the first guide 161 may be larger or smaller than the length 162L of the second guide 162.

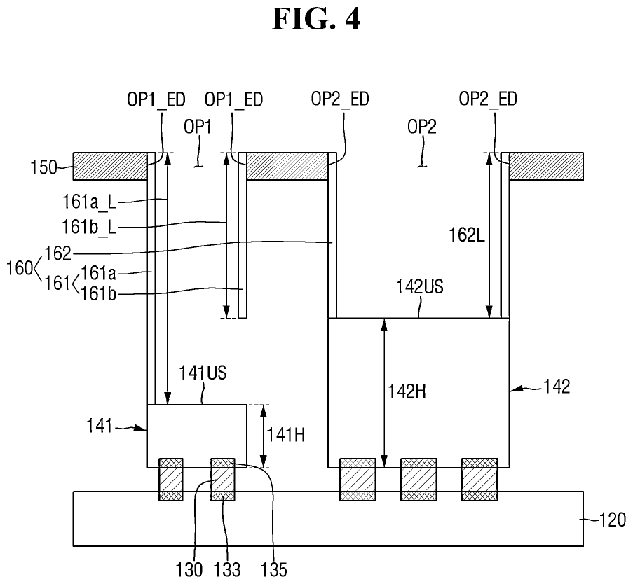

Referring to FIG. 4, in a cross-sectional view, the first guide 161 may include a first portion 161a and a second portion 162a. The first portion 161a may be farther from the second guide 162 than the second portion 161b may be. For example, a spacing from the first portion 161a to the second guide 162 may be larger than a spacing from the second portion 161b to the second guide 162.

A length 161a_L of the first portion 161a and a length 161a_L of the second portion 161b may be different from each other. For example, the length 161a_L of the first portion 161a may be greater than the length 161a_L of the second portion 161b. The first portion 161a might not be spaced apart from the first electronic device 141 in the vertical direction. On the contrary, the second portion 161b may be spaced apart from the first electronic device 141 in the vertical direction.

In FIG. 4, the length 161a_L of the second portion 161b may be equal to the length 162L of the second guide 162. However, the technical idea of the present disclosure is not necessarily limited thereto. In an example, the length 161a_L of the second portion 161b may be larger or smaller than the length 162L of the second guide 162.

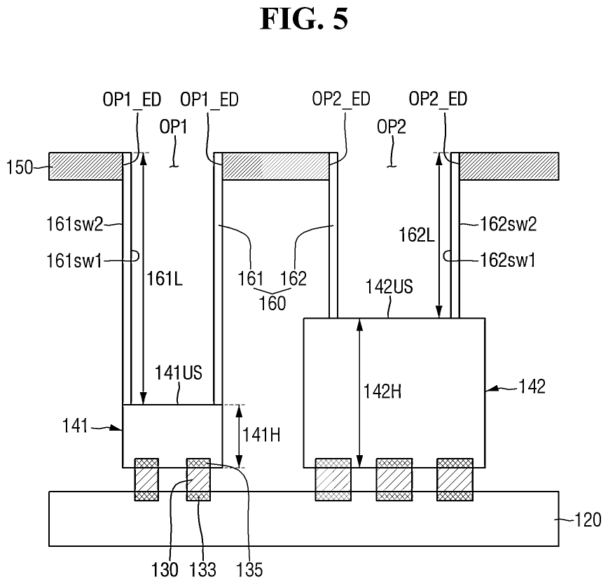

Referring to FIG. 5, the width of the second opening OP2 may be smaller than the width of the upper surface 142US of the second electronic device 142. For example, in a plan view, the area size of the second opening OP2 may be smaller than the area size of the upper surface 142US of the second electronic device 142.

At least a portion of the upper surface 142US of the second electronic device 142 might not overlap the second opening OP2 in the vertical direction. Using the soldering apparatus in FIG. 5, the light may be radiated more intensely to a target location.

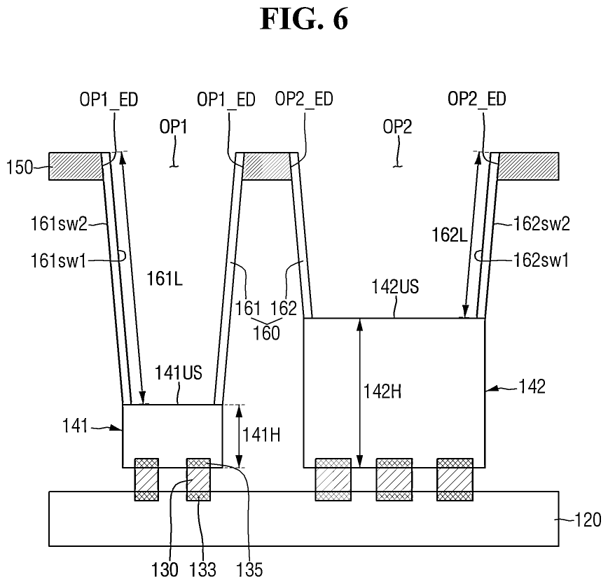

Referring to FIG. 6, each of the first guide 161 and the second guide 162 may extend in an oblique direction. The oblique direction may be different from the vertical direction.

For example, in a cross-sectional view, the spacing between the first sidewalls 161sw1 may decrease as the first sidewalls 161sw1 extend from the mask film 150 toward the first electronic device 141. In this regard, a spacing between the first sidewalls 161sw1 at a lower end of the first guide 161 may be equal to the width of the upper surface 141US of the first electronic device 141. The spacing between the first sidewalls 161sw1 at an upper end of the first guide 161 and may be equal to the width of the first opening OP1.

For example, the width of the first opening OP1 may be larger than the width of the upper surface 141US of the first electronic device 141. At least a portion of the first opening OP1 might not overlap the upper surface 141US of the first electronic device 141 in the vertical direction.

Likewise, in the cross-sectional view, a spacing between the third sidewalls 162sw1 may decrease as the third sidewalls 162sw1 extend from the mask film 150 toward the second electronic device 142. In this regard, the spacing between the third sidewalls 162sw1 at a lower end of the second guide 162 may be equal to the width of the upper surface 142US of the second electronic device 142. The spacing between the third sidewalls 162sw2 at the uppermost end of the second guide 162 may be equal to the width of the second opening OP2.

For example, the width of the second opening OP2 may be larger than the width of the upper surface 142US of the second electronic device 142. At least a portion of the second opening OP2 might not overlap the upper surface 142US of the second electronic device 142 in the vertical direction.

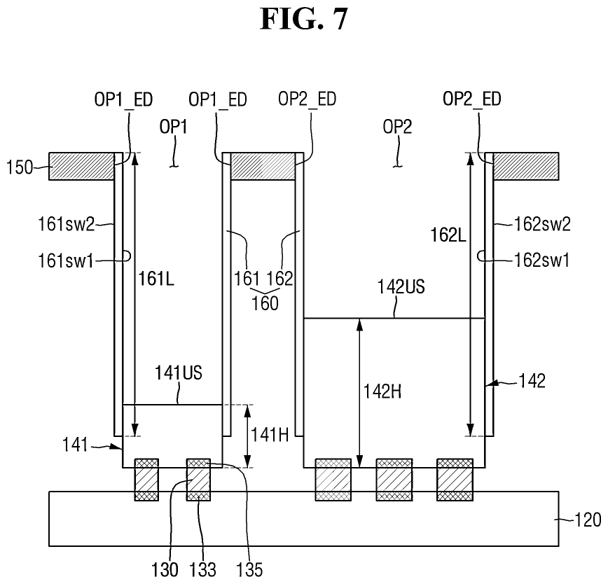

Referring to FIG. 7, the first guide 161 may overlap at least a portion of the first electronic device 141 in a horizontal direction. The horizontal direction may be a direction that intersects the vertical direction. The horizontal direction may be parallel to the upper surface 141US of the first electronic device 141.

A portion of the first guide 161 may be disposed on a sidewall of the first electronic device 141. The portion of the first guide 161 may contact the sidewall of the first electronic device 141. For example, a portion of the first sidewall 161sw1 of the first guide 161 may contact the sidewall of the first electronic device 141.

Likewise, the second guide 162 may overlap at least a portion of the second electronic device 142 in the horizontal direction.

A portion of the second guide 162 may be disposed on a sidewall of the second electronic device 142. The portion of the second guide 162 may contact the sidewall of the second electronic device 142. For example, a portion of the third sidewall 162sw1 of the second guide 162 may contact the sidewall of the second electronic device 142.

In some embodiments, in the cross-sectional view, the spacing between the first sidewalls 161sw1 may be equal to the width of the upper surface 141US of the first electronic device 141. In the cross-sectional view, the spacing between the third sidewalls 162sw1 may be equal to the width of the upper surface 142US of the second electronic device 142. However, the technical idea of the present disclosure is not necessarily limited thereto.

The first sidewall 161sw1 may be spaced apart from the sidewall of the first electronic device 141. In the cross-sectional view, the spacing between the first sidewalls 161sw1 may be greater than the width of the upper surface 141US of the first electronic device 141. Furthermore, the third sidewall 162sw1 may be spaced apart from the sidewall of the second electronic device 142. In the cross-sectional view, the spacing between the third sidewalls 162sw1 may be larger than the width of the upper surface 142US of the second electronic device 142.

In some embodiments, the width of the first opening OP1 is greater than the width of the upper surface 141US of the first electronic device 141. Furthermore, the width of the second opening OP2 is larger than the width of the upper surface 142US of the second electronic device 142. Using the soldering apparatus in FIG. 7, the light may be radiated more intensely to a target location.

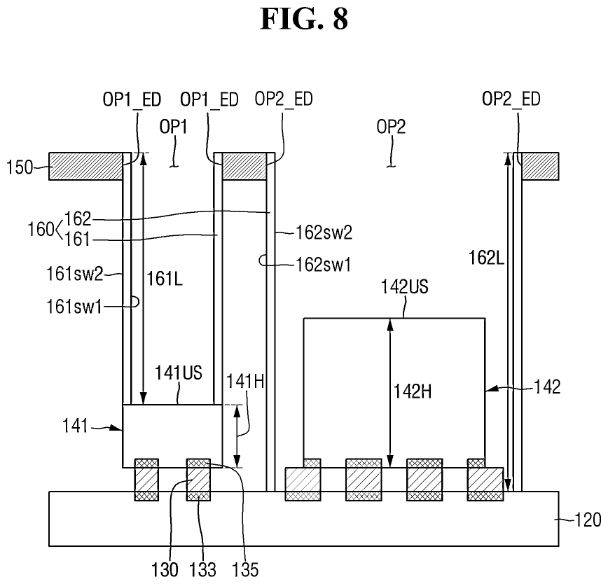

Referring to FIG. 8, the second guide 162 may extend to the PCB substrate 120. The second electronic device 142 may entirely overlap the second guide 162 in the horizontal direction.

In FIG. 8, the outermost solder ball 130, among solder balls 130 disposed under the second electronic device 142, may protrude outwardly beyond a sidewall of the second electronic device 142. Since the light provided from the light source 170 should apply heat to the solder ball 130, the second opening OP2 may entirely overlap the solder ball 130 in the vertical direction. Accordingly, the second guide 162 may extend to the PCB substrate 120. In the cross-sectional view, the spacing between the third sidewalls 162sw1 may be larger than the width of the upper surface 142US of the second electronic device 142.

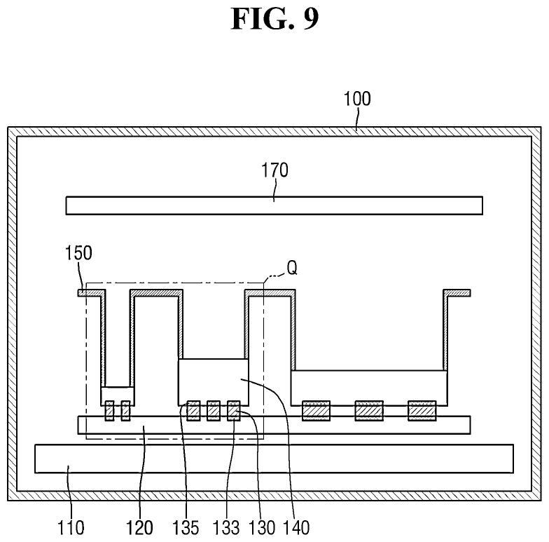

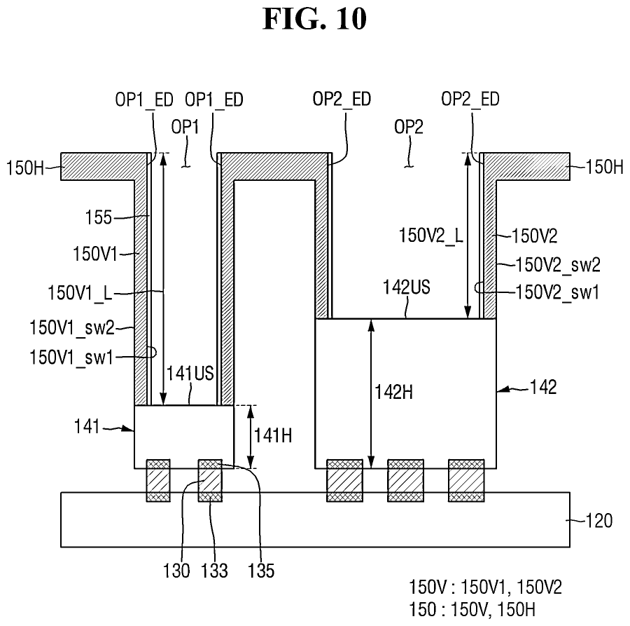

Hereinafter, with reference to FIG. 9 and FIG. 10, a soldering apparatus according to some embodiments of the present disclosure is described. For convenience of description, to the extent that an element is not described in detail with respect to this figure, it may be understood that the clement is at least similar to a corresponding element that has been described elsewhere within the present disclosure.

FIG. 9 is a diagram illustrating a soldering apparatus according to some embodiments of the present disclosure. FIG. 10 is an enlarged view of a Q area in FIG. 9.

Referring to FIG. 9 and FIG. 10, the soldering apparatus, according to some embodiments, may include the housing 100, the stage 110, the mask film 150, a reflective film 155, and the light source 170. The soldering apparatus, in accordance with the present disclosure, may be an apparatus that performs a soldering process when manufacturing a semiconductor package. For example, the soldering apparatus in accordance with the present disclosure may be an apparatus that performs a light soldering process using light.

The housing 100, the stage 110, and the light source 170 are the same as those as described above using FIG. 1 and FIG. 2, and thus to the extent that an element is not described in detail with respect to this figure, it may be understood that the element is at least similar to a corresponding clement that has been described elsewhere within the present disclosure.

In some embodiments, the mask film 150 may include a horizontal portion 150H and a vertical portion 150V. The horizontal portion 150H may include a first opening OP1 exposing the first electronic device 141 and a second opening OP2 exposing the second electronic device 142. The horizontal portion 150H may extend in the horizontal direction. The horizontal direction may be parallel to the upper surface 141US of the first electronic device 141 and the upper surface 142US of the second electronic device 142.

The vertical portion 150V may include a first vertical portion 150V1 and a second vertical portion 150V2. The first vertical portion 150V1 may be connected to the horizontal portion 150H. The first vertical portion 150V1 may extend from the end OP1_ED of the first opening OP1 toward the first electronic device 141. The first vertical portion 150V1 might not be spaced apart from the upper surface 141US of the first electronic device 141. The first vertical portion 150V1 may be in contact with the upper surface 141US of the first electronic device 141.

The second vertical portion 150V2 may be connected to the horizontal portion 150H. The second vertical portion 150V2 may extend from the end OP2_ED of the second opening OP2 toward the second electronic device 142. The second vertical portion 150V2 might not be spaced apart from the upper surface 142US of the second electronic device 142. The second vertical portion 150V2 may be in contact with the upper surface 142US of the second electronic device 142.

In some embodiments, the first vertical portion 150V1 may include a fifth sidewall 150V1_sw1 facing the first opening OP1 and a sixth sidewall 150V1_sw2 opposite thereto. In the cross-sectional view, a spacing between the fifth sidewalls 150V1_sw1 adjacent to each other may be constant as the fifth sidewalls 150V1_sw1 extend from the horizontal portion 150H of the mask film 150 toward the first electronic device 141. Furthermore, the second vertical portion 150V2 may include a seventh sidewall 150V2_sw1 facing the second opening OP2 and an eighth sidewall 150V2_sw2 opposite thereto. In the cross-sectional view, a spacing between the seventh sidewalls 150V2_sw1 adjacent to each other may be constant as the seventh sidewalls 150V2_sw1 extend from the horizontal portion 150H of the mask film 150 toward the second electronic device 142.

In some embodiments, a length 150V1_L of the first vertical portion 150V1 may be different from a length 150V2_L of the second vertical portion 150V2. For example, the length 150V1_L of the first vertical portion 150V1 may be greater than the length 150V2_L of the second vertical portion 150V2. In some embodiments, a length of the vertical portion 150V may be determined based on a size of the corresponding electronic device 140. In one example, when the height of the electronic device 140 is large, the length of the corresponding vertical portion 150V may be small. Conversely, when the height of the electronic device 140 is small, the length of the corresponding vertical portion 150V may be large.

Likewise, the area size of the opening may be determined based on the area size of the corresponding electronic device 140. In one example, when the area size of the electronic device 140 is large, the area size of the corresponding opening may be large. Conversely, when the area size of the electronic device 140 is small, the area size of the corresponding opening may be small.

In FIG. 10, the width of the first electronic device 141 is smaller than the width of the second electronic device 142. Therefore, the width of the first opening OP1 may be smaller than the width of the second opening OP2. However, the technical idea of the present disclosure is not necessarily limited thereto.

The reflective film 155 may be disposed on at least a portion of a surface of the mask film 150. The reflective film 155 may be disposed, for example, on a sidewall of the vertical portion 150V. The reflective film 155 is not disposed on an upper surface of the horizontal portion 150H. The reflective film 155 may be coated on the sidewall of the vertical portion 150V.

For example, the reflective film 155 may be disposed on the fifth sidewall 150V1_sw1 of the first vertical portion 150V1. Furthermore, the reflective film 155 may be disposed on the seventh sidewall 150V2_sw1 of the second vertical portion 150V2. The reflective film 155 may reflect light passing through the first and second openings OP1 and OP2 therefrom. The reflective film 155 may include a reflective material. For example, the reflective film 155 may be made of a polymer material such as PPA (polyphthalamide) or a highly reflective metal powder or ceramic powder. The highly reflective ceramic powder may be made of TiO₂, Al₂O₃, Nb₂O₅, Al₂O₃, and/or ZnO. The highly reflective metal powder may be made of aluminum (Al) or silver (Ag). Furthermore, the reflective material may be a mirror-like material. However, the technical idea of the present disclosure is not necessarily limited thereto.

The reflective film 155 may be made of the same material as the material included in the guide 160 described above using FIG. 1 and FIG. 2.

When performing a light soldering process using a soldering apparatus, according to some embodiments, light does not transmit through the reflective film 155. Therefore, the light may be cast only to a target area. The reflective film 155 may be appropriately coated to prevent the light from being cast to a portion vulnerable to light. Thus, using the soldering apparatus of the present disclosure, a semiconductor package with increased reliability may be manufactured.

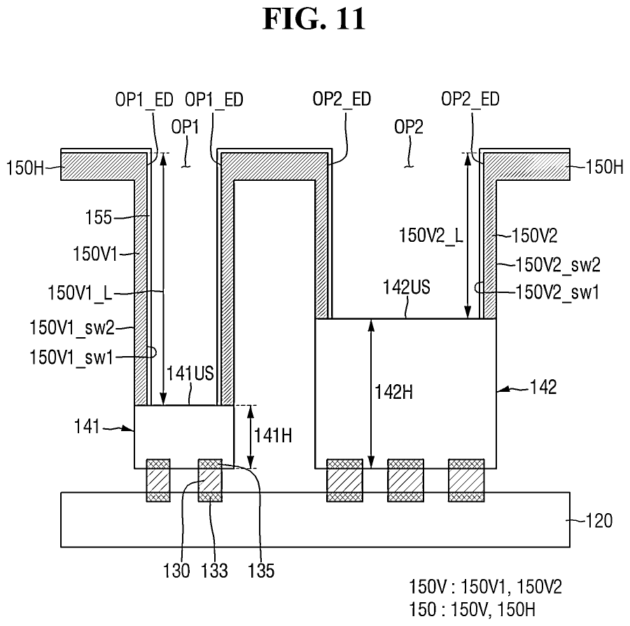

Hereinafter, a soldering apparatus according to some embodiments of the present disclosure is described with reference to FIGS. 11 to 15. For convenience of description, to the extent that an element is not described in detail with respect to this figure, it may be understood that the element is at least similar to a corresponding element that has been described elsewhere within the present disclosure. FIGS. 11 to 15 are diagrams illustrating a soldering apparatus according to some embodiments of the present disclosure.

First, referring to FIG. 11, the reflective film 155 may be further coated on the upper surface of the horizontal portion 150H. The reflective film 155 may be coated on an entirety of a surface of the mask film 150. For example, the reflective film 155 may be coated on an entirety of a surface onto which the light may be cast.

The light emitted from the light source 170 may be reflected from the reflective film 155. Therefore, the light does not travel through the horizontal portion 150H. This may prevent the light from being cast to an unwanted area.

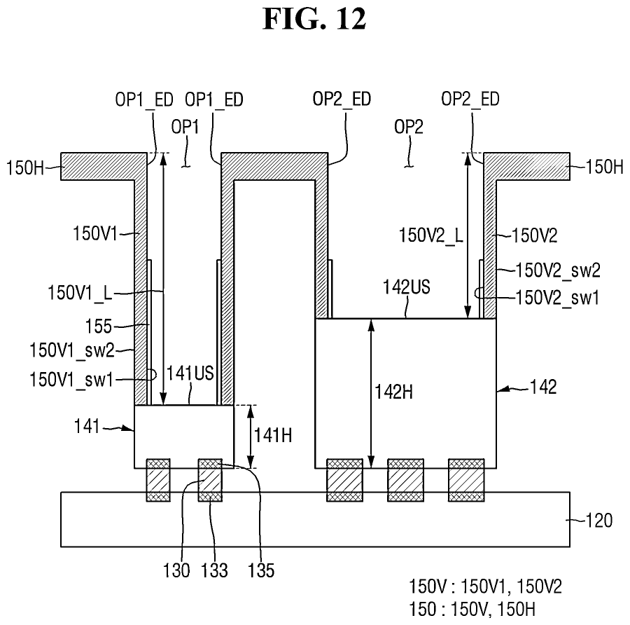

Referring to FIG. 12, the reflective film 155 is disposed on at least a portion of the sidewall of the vertical portion 150V, but might not be disposed on a remaining portion of the sidewall of the vertical portion 150V. The reflective film 155 extends from the upper surface 141US of the first electronic device 141, but does not extend to an upper end of the first vertical portion 150V1. Likewise, the reflective film 155 extends from the upper surface 142US of the second electronic device 142, but does not extend to an upper end of the second vertical portion 150V2.

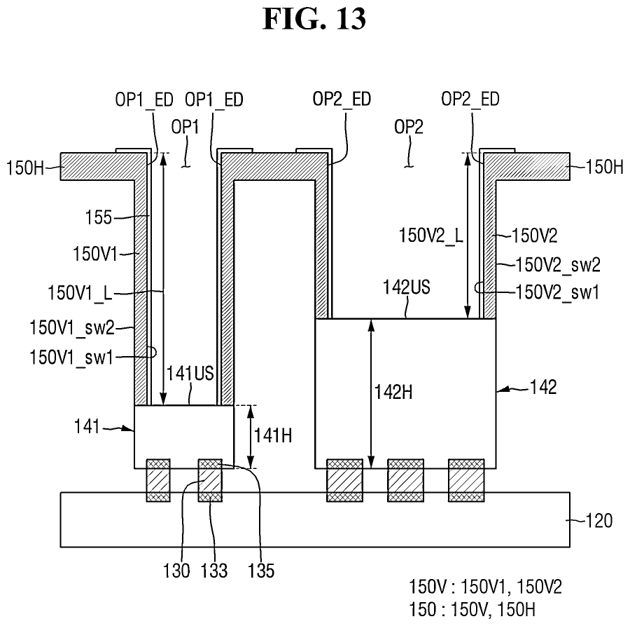

Referring to FIG. 13, the reflective film 155 may be coated on the sidewall of the vertical portion 150V, and may be coated on at least a portion of the upper surface of the horizontal portion 150H. For example, the reflective film 155 may cover the at least a portion of the upper surface of the horizontal portion 150H and might not cover a remaining portion of the upper surface of the horizontal portion 150H so as to be exposed. Thus, an amount of light provided to the PCB substrate 120 may be more delicately controlled.

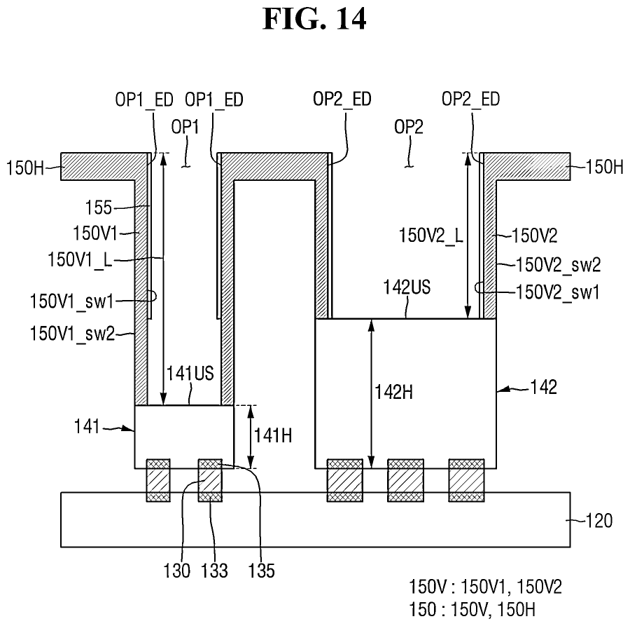

Referring to FIG. 14, the reflective film 155 may be disposed on at least a portion of the sidewall of the vertical portion 150V, but might not be disposed on a remaining portion of the sidewall of the vertical portion 150V. The reflective film 155 extends from the uppermost end of the first vertical portion 150V1, but does not extend to the upper surface 141US of the first electronic device 141. Likewise, the reflective film 155 extends from the top end of the second vertical portion 150V2, but does not extend to the upper surface 142US of the second electronic device 142.

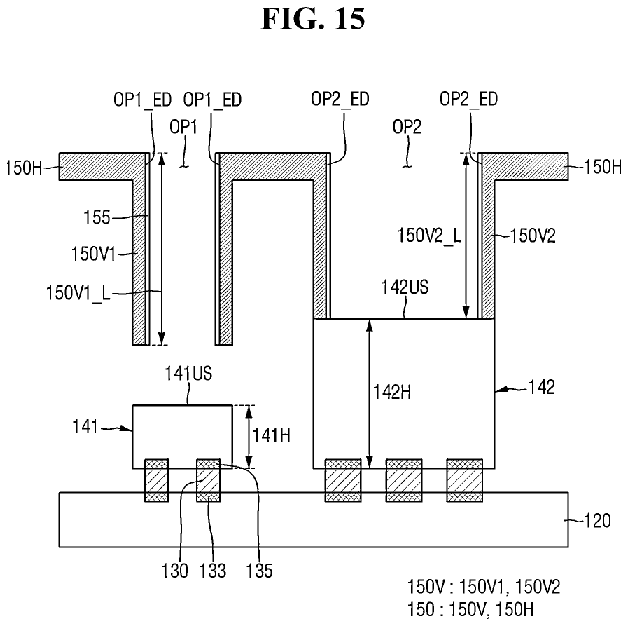

Referring to FIG. 15, the first vertical portion 150V1 may be spaced apart from the first electronic device 141 in the vertical direction. The second vertical portion 150V2 is not spaced apart from the second electronic device 142 in the vertical direction. In this regard, the length 150V1_L of the first vertical portion 150V1 may be greater than the length 150V2_L of the second vertical portion 150V2. However, the technical idea of the present disclosure is not necessarily limited thereto. In an example, the length 150V1_L of the first vertical portion 150V1 may be equal to the length 150V2_L of the second vertical portion 150V2, or may be smaller than the length 150V2_L of the second vertical portion 150V2.

Furthermore, the reflective film 155 is shown as being coated only on the fifth sidewall 150V1_sw1 of the first vertical portion 150V1. However, the present disclosure is not necessarily limited thereto. The reflective film 155 may be further coated on a bottom surface of the first vertical portion 150V1 and on at least a portion of the sixth sidewall 150V1_sw2 of the first vertical portion 150V1.

As described above using FIGS. 4 to 8, each of the first and second vertical portions 150V1 an 150V2 may extend in the oblique direction rather than the vertical direction. Furthermore, the first and second vertical portions 150V1 and 150V2 may overlap the sidewalls of the first and second electronic devices 141 and 142, respectively, in the horizontal direction. Furthermore, at least a portion of each of the first and second vertical portions 150V1 and 150V2 may be in contact with the PCB substrate 120.

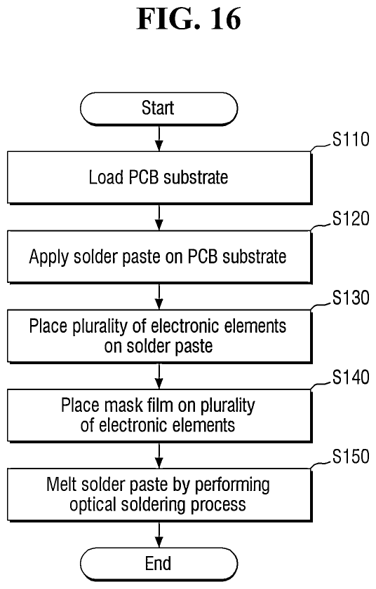

Hereinafter, with reference to FIGS. 16 to 23, a method for manufacturing a semiconductor package using a soldering apparatus, according to some embodiments of the present disclosure, is described. FIGS. 16 to 23 are diagrams illustrating a method of manufacturing a semiconductor package using a soldering apparatus according to some embodiments.

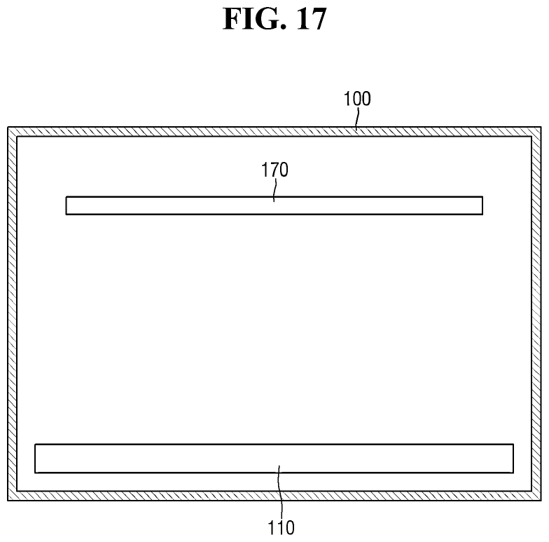

For reference, FIG. 16 is a flowchart illustrating a method of manufacturing a semiconductor package using a soldering apparatus according to some embodiments. FIGS. 17 to 23 are diagrams of intermediate structures corresponding to intermediate steps of a method of manufacturing a semiconductor package using a soldering apparatus according to some embodiments.

First, referring to FIG. 17, the soldering apparatus may be provided. The soldering apparatus may include the housing 100, the stage 110, and the light source 170.

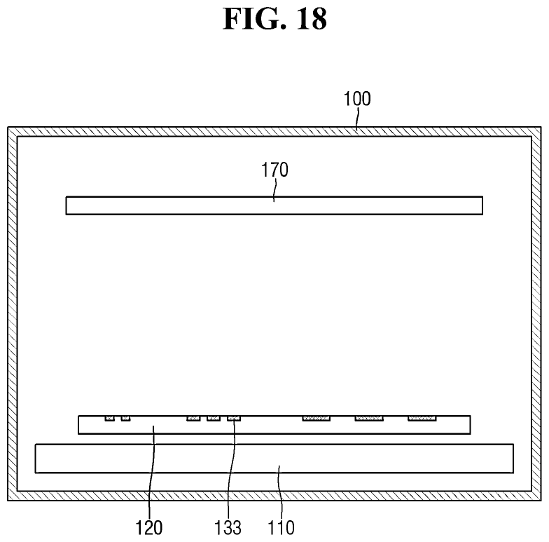

Referring to FIG. 16 and FIG. 18, the PCB substrate 120 may be loaded on the stage 110 in S110. The PCB substrate 120 may be loaded onto the stage 110 of the soldering apparatus.

Referring to FIG. 16 and FIG. 19, a solder paste 130P may be applied on the PCB substrate 120 in S120.

The solder paste 130P may be applied on the PCB substrate 120. For example, the solder paste 130P may be applied on the substrate pad 133. The solder paste 130P may include a conductive material. For example, the solder paste 130P may include copper (Cu), tin (Sn), silver (Ag), alloys thereof, and/or alloys thereof including bismuth (Bi). In one example, the solder paste 130P may be made of an alloy containing about 96.5% by weight of copper, 3.0% by weight of tin, and 0.5% by weight of silver. However, the technical idea of the present disclosure is not necessarily limited thereto.

The solder paste 130P may be applied in a screen-printing, stencil-printing, or direct-printing manner.

For example, when the solder paste 130P is applied using a screen-printing technique, a metal mask including plurality of openings defined therein is disposed on the PCB substrate 120. In this regard, the opening of the metal mask may be aligned with an area (e.g., the substrate pad) on which the solder paste 130P is mounted. Next, the older paste 130P is sprayed on the metal mask. Afterwards, a squeegee of a screen-printer pushes the sprayed solder paste 130P into the opening of the metal mask. Through this process, the solder paste 130P may be applied.

When the solder paste 130P cannot be applied using the screen-printing technique, the solder paste 130P may be applied using a stencil-printing technique or a direct-printing technique.

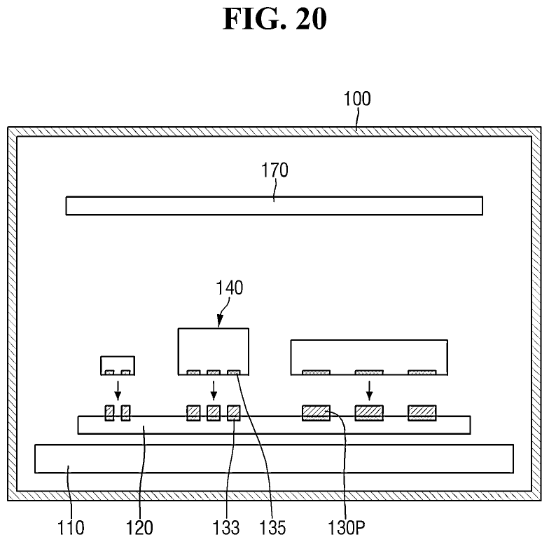

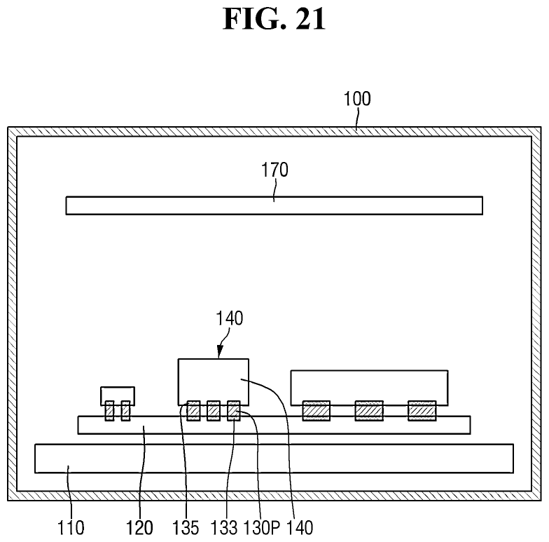

Referring to FIG. 16, FIG. 20, and FIG. 21, the plurality of electronic devices 140 may be disposed on the solder paste 130P in S130.

The plurality of electronic devices 140 are disposed on the solder paste 130P. The plurality of electronic devices 140 may be aligned and arranged so that a lower surface of the chip pad 135 is in contact with the solder paste 130P. The plurality of electronic devices 140 may be placed, for example, in a pick and place manner. However, the present disclosure is not necessarily limited thereto. In FIG. 20 and FIG. 21, three electronic devices are shown as being arranged, but the technical idea of the present disclosure is not necessarily limited thereto.

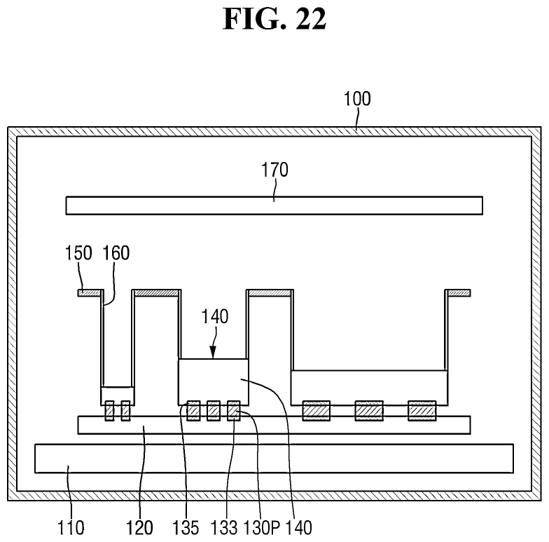

Referring to FIG. 16 and FIG. 22, the mask film 150 may be disposed on the plurality of electronic devices 140 in S140.

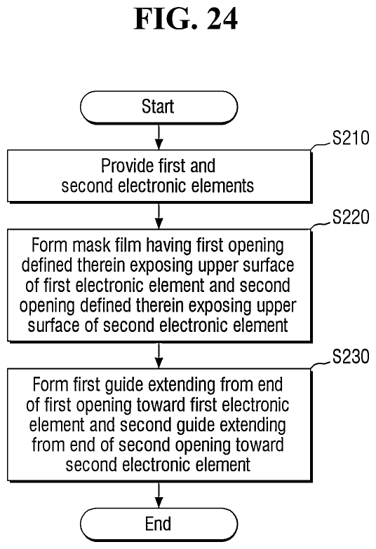

The guide 160 may be disposed under the mask film 150. The mask film 150 and the guide 160 may be manufactured with reference to the sizes of the electronic devices 140. A detailed description thereof will be provided later with reference to FIGS. 24 to 30. The mask film 150 might not cover each of the plurality of electronic devices 140 so as to be exposed.

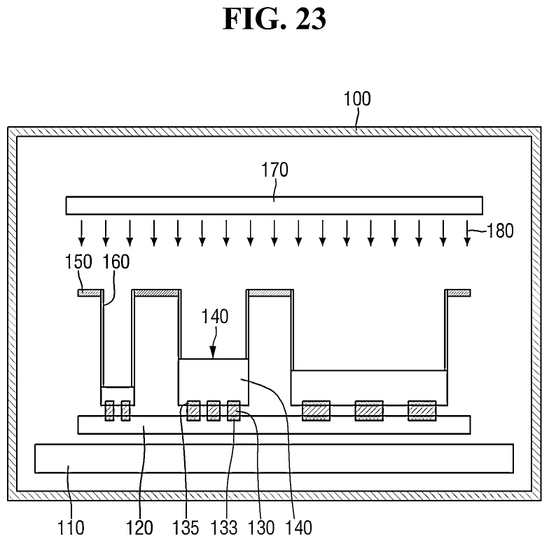

Referring to FIG. 16 and FIG. 23, the solder paste 130P may be melted by performing a light soldering process in S150.

The light source 170 may cast the light toward the plurality of electronic devices 140 (see a reference numeral 180). The light may be IPL (intense pulsed light). The IPL refers to short, strong pulsed light with a wide wavelength spectrum. The solder paste 130P may be melted using the IPL. The solder paste 130P may be melted to form the solder ball 130.

In some embodiments, the number of pulses of IPL may be about 6 or more. For example, the number of pulses of IPL may be in a range of about 6 to about 8. However, the technical idea of the present disclosure is not necessarily limited thereto.

In some embodiments, as the guide 160 is made of a reflective material, the IPL might not be cast to an area where the solder paste 130P is not disposed. Accordingly, damage applied to the PCB substrate 120 or the plurality of electronic devices 140 may be reduced. For example, a semiconductor package with increased reliability may be manufactured.

The mask film and the reflective film as described above using FIG. 9 and FIG. 10 may be disposed on the plurality of electronic devices 140. Even in this case, as the reflective film is made of the reflective material, the IPL might not be cast to areas where solder paste 130P is not disposed. Accordingly, the damage applied to the PCB substrate 120 or the plurality of electronic devices 140 may be reduced. For example, a semiconductor package with increased reliability may be manufactured.

Hereinafter, a method for manufacturing a soldering apparatus, according to some embodiments of the present disclosure, is described with reference to FIGS. 24 to 27. FIGS. 24 to 27 are diagrams illustrating a method of manufacturing a soldering apparatus according to some embodiments. For example, FIGS. 24 to 27 may be diagrams showing a method for manufacturing a mask film and a guide having a cross section of FIG. 2.

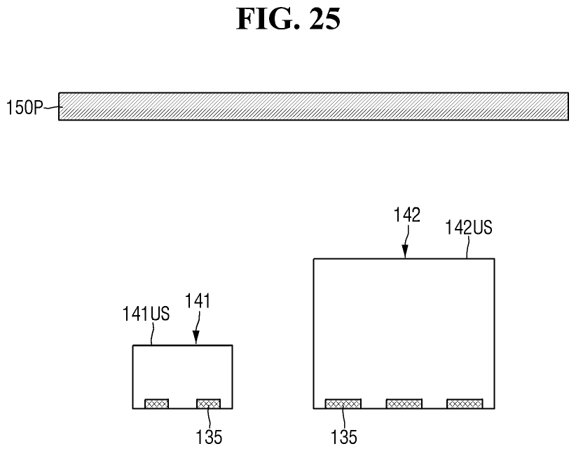

For reference, FIG. 24 is a flowchart illustrating a method for manufacturing a soldering apparatus according to some embodiments. FIGS. 25 to 27 are diagrams of intermediate structures corresponding to intermediate steps of a method for manufacturing a soldering apparatus according to some embodiments.

First, referring to FIG. 24 and FIG. 25, the first and second electronic devices 141 and 142 may be provided in S210. Each of the first and second electronic devices 141 and 142 may include the chip pad 135.

In some embodiments, the size of the first electronic device 141 may be different from the size of the second electronic device 142. In one example, the height of the first electronic device 141 may be smaller than the height of the second electronic device 142.

A pre-mask film 150P may be provided on the first and second electronic devices 141 and 142. The pre-mask film 150P may be made of a metal material. However, the technical idea of the present disclosure is not necessarily limited thereto.

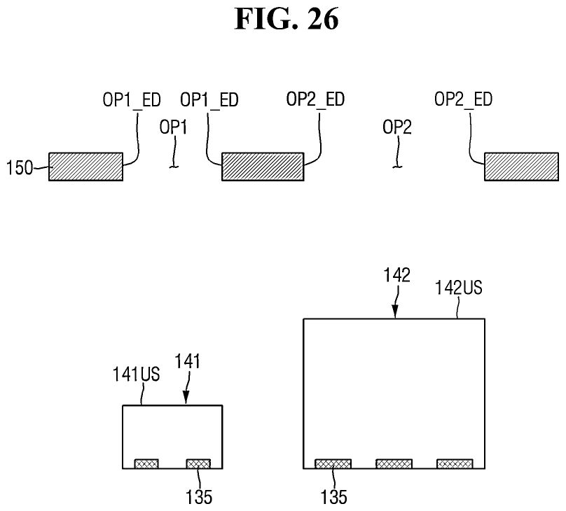

Referring to FIG. 24 and FIG. 26, the mask film 150 including the first opening OP1 defined therein exposing the upper surface 141US of the first electronic device 141, and the second opening OP2 defined therein exposing the upper surface 142US of the second electronic device 142 may be formed in S220.

The mask film 150 may be formed by removing a portion of the pre-mask film 150P. The portion of the pre-mask film 150P may be removed to form the first opening OP1 and the second opening OP2. The first opening OP1 exposes the upper surface 141US of the first electronic device 141. The second opening OP2 exposes the upper surface 142US of the second electronic device 142.

The end OP1_ED of the first opening OP1 may be the boundary between the first opening OP1 and the mask film 150. In some embodiments, in a cross-sectional view, the spacing between both opposing ends OP1_ED of the first opening OP1 may be equal to the width of the first electronic device 141. However, the present disclosure is not necessarily limited thereto. The spacing between both opposing ends OP1_ED of the first opening OP1 may be the width of the first opening OP1.

The end OP2_ED of the second opening OP2 may be the boundary between the second opening OP2 and the mask film 150. In some embodiments, in a cross-sectional view, a spacing between both opposing ends OP2_ED of the second opening OP2 may be equal to the width of the second electronic device 142. However, the present disclosure is not necessarily limited thereto. The spacing between both opposing ends OP2_ED of the second opening OP2 may be the width of the second opening OP2.

In some embodiments, the width of the first electronic device 141 may be smaller than the width of the second electronic device 142. Accordingly, the width of the first opening OP1 may be smaller than the width of the second opening OP2. In this way, the mask film 150 may be manufactured with reference to the sizes of the first and second electronic devices 141 and 142.

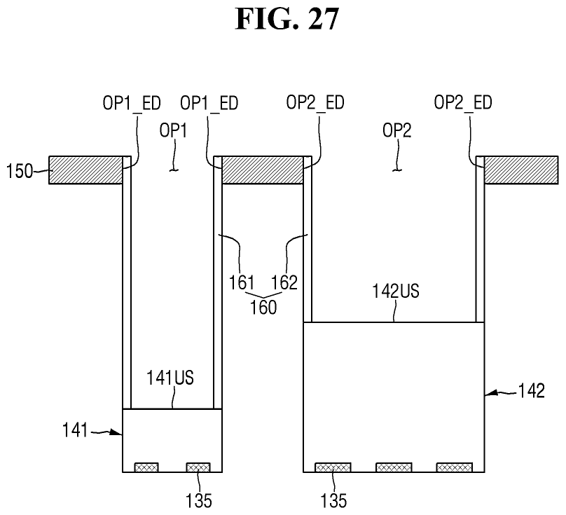

Referring to FIG. 24 and FIG. 27, the first guide 161 and the second guide 162 may be formed in S230.

The first guide 161 may be connected to the mask film 150 and extend toward the first electronic device 141. The first guide 161 may extend from the end OP1_ED of the first opening OP1 toward the first electronic device 141.

The second guide 162 may be connected to the mask film 150 and extend toward the second electronic device 142. The second guide 162 may extend from the end OP2_ED of the second opening OP2 toward the second electronic device 142.

In some embodiments, the vertical length of the first guide 161 may be larger than the vertical length of the second guide 162. This may be because the height of the first electronic device 141 is smaller than the height of the second electronic device 142. For example, the vertical length of the first guide 161 may be determined based on the height of the first electronic device 141. The vertical length of the second guide 162 may be determined based on the height of the second electronic device 142. In this way, the first and second guides 161 and 162 may be manufactured with reference to the sizes of the first and second electronic devices 141 and 142.

Since the first guide 161 and the second guide 162 face toward the first and second openings OP1 and OP2, respectively, the first guide 161 and the second guide 162 may reflect the light provided through the first and second openings OP and OP2 therefrom. This may prevent the light from being cast to an unwanted area, for example, an area where heat does not need to be supplied. Accordingly, a semiconductor package with increased reliability may be manufactured.

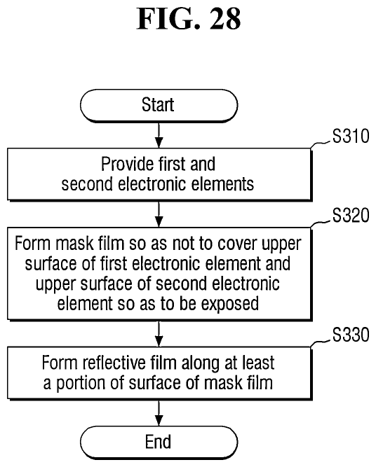

Hereinafter, a method for manufacturing a soldering apparatus according to some embodiments of the present disclosure is described with reference to FIGS. 28 to 30. FIGS. 28 to 30 are diagrams illustrating a method of manufacturing a soldering apparatus according to some embodiments. For example, FIGS. 28 to 30 may be diagrams showing a method of manufacturing a mask film and a reflective film having the cross section of FIG. 10.

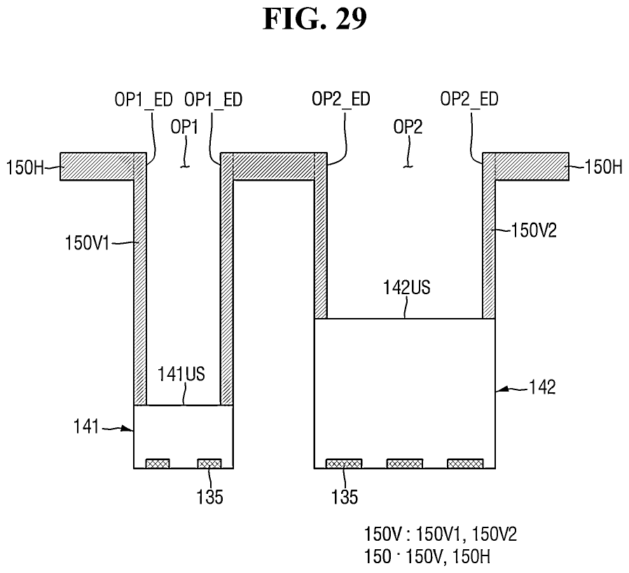

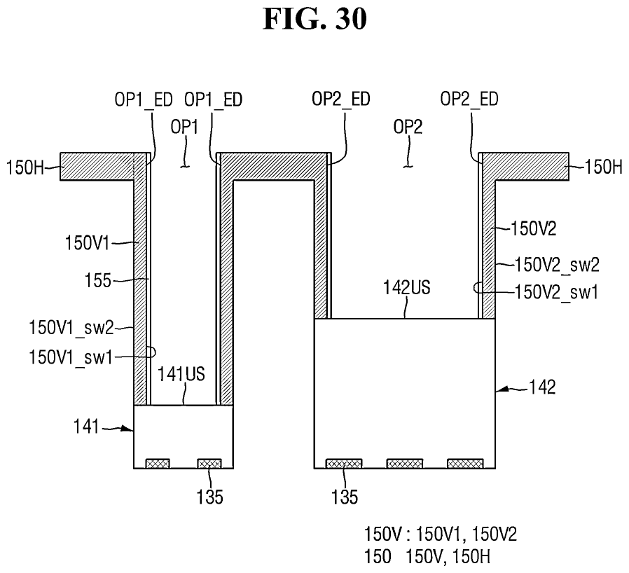

For reference, FIG. 28 is a flowchart illustrating a method for manufacturing a soldering apparatus according to some embodiments. FIG. 29 and FIG. 30 are diagrams of intermediate structures corresponding to intermediate steps of a method for manufacturing a soldering apparatus according to some embodiments.

Referring to FIG. 25 and FIG. 28, the first and second electronic devices 141 and 142 may be provided in S310. Each of the first and second electronic devices 141 and 142 may include the chip pad 135.

In some embodiments, the size of the first electronic device 141 may be different from the size of the second electronic device 142. In one example, the height of the first electronic device 141 may be smaller than the height of the second electronic device 142.

The pre-mask film 150P may be provided on the first and second electronic devices 141 and 142. The pre-mask film 150P may be made of a metal material, but the technical idea of the present disclosure is not necessarily limited thereto.

Referring to FIG. 28 and FIG. 29, the mask film 150 might not cover the upper surface 141US of the first electronic device 141 and the upper surface 142US of the second electronic device 142 and may be exposed in S320. The mask film 150 may be formed by removing a portion of the pre-mask film 150P.

The mask film 150 may include the horizontal portion 150H and the vertical portion 150V. The horizontal portion 150H may include the first opening OP1 defined therein exposing the first electronic device 141 and the second opening OP2 defined therein exposing the second electronic device 142. The horizontal portion 150H may extend in the horizontal direction. The horizontal direction may be parallel to the upper surface 141US of the first electronic device 141 and the upper surface 142US of the second electronic device 142.

The vertical portion 150V may include the first vertical portion 150V1 and the second vertical portion 150V2. The first vertical portion 150V1 may be connected to the horizontal portion 150H. The first vertical portion 150V1 may extend from the end OP1_ED of the first opening OP1 toward the first electronic device 141. The first vertical portion 150V1 might not be spaced apart from the upper surface 141US of the first electronic device 141. The first vertical portion 150V1 may be in contact with the upper surface 141US of the first electronic device 141.

In the process of removing the pre-mask film 150P, the portion of the pre-mask film 150P may flow in the vertical direction. Thus, the vertical portion 150V may be formed.

Referring to FIG. 29 and FIG. 30, the reflective film 155 may be formed along at least a portion of the surface of the mask film 150 in S330.

In some embodiments, the first vertical portion 150V1 may include the fifth sidewall 150V1_sw1 facing the first opening OP1 and the sixth sidewall 150V1_sw2 opposite thereto. The second vertical portion 150V2 may include the seventh sidewall 150V2_sw1 facing the second opening OP2 and the eighth sidewall 150V2_sw2 opposite thereto.

The reflective film 155 may be formed on the fifth sidewall 150V1_sw1 of the first vertical portion 150V1 and the seventh sidewall 150V2_sw1 of the second vertical portion 150V2. The reflective film 155 may entirely cover the fifth sidewall 150V1_sw1 of the first vertical portion 150V1 and the seventh sidewall 150V2_sw1 of the second vertical portion 150V2.

The reflective film 155 might not be formed on the sixth sidewall 150V1_sw2 of the first vertical portion 150V1 and the eighth sidewall 150V2_sw2 of the second vertical portion 150V2.

Since the reflective film 155 is formed so as to face toward the first and second openings OP1 and OP2, the reflective film 155 may reflect the light provided through the first and second openings OP1 and OP2 therefrom. This may prevent the light from being cast to an unwanted area, for example, an area where heat does not need to be supplied. Accordingly, a semiconductor package with increased reliability may be manufactured.

Although the embodiments of the present disclosure have been described above with reference to the accompanying drawings, the present disclosure might not necessarily be limited to the embodiments described herein and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not necessarily restrictive but illustrative in all respects.

1. A soldering apparatus, comprising:
a stage including a plurality of electronic devices loaded thereon;
a light source disposed on the stage and configured to cast light toward the plurality of electronic devices; and
a mask film disposed between the light source and the plurality of electronic devices, wherein the mask film has openings exposing at least a portion of each of the plurality of electronic devices;
a guide connected to the mask film, the guide extending toward the plurality of electronic devices,
wherein the guide includes a reflective material.

2. The soldering apparatus of claim 1, wherein the plurality of electronic devices include a first electronic device and a second electronic device,
wherein the guide includes a first guide disposed on the first electronic device and a second guide disposed on the second electronic device, and
wherein a length of the first guide is smaller than a length of the second guide.

3. The soldering apparatus of claim 2, wherein a height of the first electronic device is greater than a height of the second electronic device.

4. The soldering apparatus of claim 1, wherein the guide reflects the light.

5. The soldering apparatus of claim 1, wherein the guide includes a plurality of first sidewalls facing the opening and a plurality of second sidewall opposite to the first sidewalls, and
wherein in a cross-sectional view, a spacing between neighboring pairs of the first sidewalls is constant as the first sidewalls extend from the mask film to the plurality of electronic devices.

6. The soldering apparatus of claim 1, wherein the guide includes a plurality of first sidewalls facing the opening and a plurality of second sidewall opposite to the first sidewalls, and
wherein in a cross-sectional view, a spacing between neighboring pairs of the first sidewalls decreases as the first sidewalls extend from the mask film to the plurality of electronic devices.

7. The soldering apparatus of claim 1, wherein the light passes through the opening and is cast to the plurality of electronic devices, and
wherein the light does not pass through the guide.

8. The soldering apparatus of claim 1, wherein, an area size of the opening is equal to or smaller than an area size of each of the plurality of electronic devices.

9. The soldering apparatus of claim 1, wherein a printed circuit board (PCB) substrate is disposed between the stage and the plurality of electronic devices,
wherein solder paste is disposed between the plurality of electronic devices and the PCB substrate, and
wherein the light melts the solder paste.

10. The soldering apparatus of claim 1, wherein the light does not pass through the mask film.

11. A soldering apparatus, comprising:
a stage on which a printed circuit board (PCB) substrate, and first and second electronic devices disposed on the PCB substrate are loaded;
a light source disposed on the stage and configured to provide light toward each of the first and second electronic devices; and
a mask film disposed between the light source and the first and second electronic devices, the mask film exposing the first and second electronic devices; and
a reflective film disposed on at least a portion of a surface of the mask film,
wherein the mask film includes:
a horizontal portion having a first opening exposing the first electronic device, and a second opening exposing the second electronic device;
a first vertical portion extending from an end of the first opening toward the first electronic device; and
a second vertical portion extending from an end of the second opening toward the second electronic device,
wherein the reflective film includes a reflective material.

12. The soldering apparatus of claim 11, wherein the reflective film is disposed on a sidewall of the first vertical portion facing the first opening.

13. The soldering apparatus of claim 12, wherein the reflective film is disposed on an upper surface of the horizontal portion.

14. The soldering apparatus of claim 11, wherein a length of the first vertical portion and a length of the second vertical portion are different from each other.

15. The soldering apparatus of claim 11, wherein the first vertical portion is spaced apart from an upper surface of the first electronic device in a vertical direction.

16. The soldering apparatus of claim 15, wherein the second vertical portion contacts an upper surface of the second electronic device in the vertical direction.

17. The soldering apparatus of claim 11, wherein solder paste is disposed between each of the first and second electronic devices and the PCB substrate, and
wherein the light is configured to melt the solder paste.

18. A method for manufacturing a semiconductor package, the method comprising:
loading a printed circuit board (PCB) substrate;
applying solder paste on the PCB substrate;
placing a plurality of electronic devices on the solder paste;
placing a mask film on the plurality of electronic devices; and
casting light toward the plurality of electronic devices using a light source that is spaced apart from the plurality of electronic devices, to perform a light soldering process,
wherein the mask film is disposed between the light source and the plurality of electronic devices,
wherein the mask film includes:
a horizontal portion having an opening defined therein exposing at least a portion of each of the plurality of electronic devices; and
a vertical portion extending from an end of the opening toward each of the plurality of electronic devices, and
wherein a reflective material is coated on a surface of the vertical portion.

19. The method of claim 18, wherein the light is reflected from the reflective material coated on the surface of the vertical portion and irradiates the solder paste.

20. The method of claim 18, wherein the opening entirely overlaps the solder paste in a vertical direction.

21-26. (canceled)
